(19) United States
(12) Patent Application Publication
(10) Pub. No.: US 2016/0204291 A1
(43) Pub. Date: Jul. 14, 2016

(54) SOLAR CELL HAVING QUANTUM WELL STRUCTURE AND METHOD FOR MANUFACTURING SAME

(71) Applicant: CHEONGJU UNIVERSITY INDUSTRY & ACADEMY COOPERATION FOUNDATION, Cheongju-si, Chungcheongbuk-do (KR)

(72) Inventor: Kwang-Ho KIM, Daejeon (KR)

(21) Appl. No.: 14/410,108

(22) PCT Filed: Jun. 5, 2013
(86) PCT No.: PCT/KR2013/004959

§ 371 Date: Dec. 22, 2014

(30) Foreign Application Priority Data
Jun. 25, 2012 (KR) 10-2012-0068180

(51) Int. Cl. H01L 31/0352; H01L 31/0368; H01L 31/0224; H01L 31/0236; H01L 31/18; H01L 31/0376; H01L 31/0216

(52) U.S. Cl. CPC H01L 31/035254; H01L 31/03762; H01L 31/03682; H01L 31/02168; H01L 31/02366; H01L 31/1868; H01L 31/1804; H01L 31/022458

(57) ABSTRACT

The present invention provides a practical solar cell having a multiple quantum well structure and a method for manufacturing the same, and the heterostructure solar cell is capable of reducing the transmission loss of solar light and the short wavelength loss of solar light by inserting a multi-layer quantum well structure between p- and n-type semiconductors, thereby obtaining a high-efficiency solar cell which can overcome the limitations of theoretical conversion efficiency and reducing manufacturing costs.

### TECHNICAL FIELD

The present invention relates to a solar cell and a method of manufacturing the solar cell, and more specifically to a solar cell having a multiple quantum well structure and a method for manufacturing the same that are available for practical usage, wherein a high-efficiency solar cell that can overcome limitations in a theoretical conversion efficiency limit, and wherein manufacturing cost can be reduced by inserting a multi-layer quantum well structure between p-type and n-type semiconductors in a heterostructure solar cell, so as to reduce transmission loss of solar light and short wavelength loss of solar light.

The present invention has been developed as part of a research project (Title of research program: Basic Science Research Program, Title of research assignment: Fabrication and evaluation of silicon quantum well structures for solar cells applications) funded by Ministry of Education (2010-0021828) of the Korean Government.

### BACKGROUND ART

The importance of enhancing efficiency in commercial silicon-based solar cells and of producing the same at a low manufacturing cost is increasing on a daily basis. Si corresponds to a substance, which has already been proven to have excellent electrical, chemical, and mechanical properties, and to be non-toxic, easily available, and stable in the field of the semiconductor industry. A first generation solar cell is based on the use of high-quality silicon, and, herein, by using such high-quality silicon, although high efficiency is expected due to its low defect density, high-quality silicon has reached its marginal efficiency in single band gap devices.

Under such circumstances, the need for enhancing structures and process technologies in order to realize high-efficiency silicon-based solar cells is becoming increasingly more important.

Most particularly, transmission loss, quantum loss, electron-hole recombination loss, surface reflection loss of the solar cell, loss caused by current-voltage characteristics, and so on, may occur due to the manufacturing process, and, herein, in order to improve conversion efficiency, it will be required to investigate (or research) from which part of the solar cell the loss occurs, and to devise a solution that can minimize the loss by improving the structural design and manufacturing process of the solar cell.

### LIST OF RELATED ART DOCUMENTS

### Non Patent Documents

(Non Patent Document 1) 1. Z.-H. Lu, D. J. Lockwood, and J. M. Baribeau, “Quantum confinement and Light emission in SiO2/Si superlattices”, Nature, 378, 258-260 (1995).
(Non Patent Document 2)2. M. A. Green, Solar Cells, Prentice-Hall, Englewood Cliffs, N.J. (1982).
(Non Patent Document 3)3. M. A. Green, Third Generation Photovoltaics, Springer-Verlag, Berlin Heidelberg (2003)
(Non Patent Document 4)4. G. Conibeer, M. Green, E.-C. Cho, D. Konig, Y.-H. Cho, T. Fangsuwannarak, G. Scardera, E. Pink, Y. Huang, T. Puzzer, S. Huang, D. Song, C. Flynn, S. Park, X. Hao and D. Mansfield “Silicon quantum dot nanostructures for tandem photovoltaic cells”, Thin Solid Films, 516(20), 6748-6756 (2008).
(Non Patent Document 5)5. D. J. Lockwood, Z. H. Lu, and J.-M. Baribeau, “Quantum Confined Luminescence in Si/SiO2 Superlattices”, Physical Review Letters, 76(3), 539-541 (1996).
(Non Patent Document 6)6. L. Pavesi and D. J. Lockwood (Eds.), [Silicon photonics], Springer, Berlin, Topics Appl. Phys. 94, 1-50 (2004).
(Non Patent Document 7)7. K.-H. Kim, H.-J Kim, P. Jong, C. Jung, and K. Seomoon, “Properties of Low-Temperature Passivation of Silicon pith ALD Al2O3 Films and their PV Applications”, Electronic Materials Letters, 7(2), 171-174 (2011).
(Non Patent Document 8)8. K.-H. Kim, J.-H. Kim, P. Jang, C. Jung, and K. Seomoon, Properties of Si/SiOx quantum well structure for solar cells applications, Proceedings of SPIE, Vol. 8111, 81111D1-81111D7 (2011).

### DISCLOSURE

### Technical Problem

Accordingly, an objective of the present invention is to provide a solar cell having a multiple quantum well structure and a method for manufacturing the same, wherein conversion efficiency is significantly improved by minimizing various losses due to the manufacturing process of the solar cell.

Additionally, another objective of the present invention is to provide a solar cell having a quantum well structure and a method for manufacturing the same that are available for practical usage and that can increase efficiency of the solar cell by realizing a structure, wherein a multi-layer quantum well structure is inserted between p-type and n-type semiconductors of a pn-heterojunction solar cell, through an increase in effective energy gap and a passivation effect.

Yet another objective of the present invention is to provide a solar cell having a multiple quantum well structure and a method for manufacturing the same that are available for practical usage, wherein a quantum well structure having favorable electrical properties is formed on a semiconductor substrate, and wherein an amorphous or a polycrystalline silicon emitters having an adequate thickness is used, when manufacturing a pn-heterojunction solar cell having a multi-layer quantum well structure inserted therein.

Furthermore, yet another objective of the present invention is to provide a solar cell having a multiple quantum well structure and a method for manufacturing the same that are available for practical usage and that can reduce the manufacturing cost by forming metallic electrodes applicable to a screen printing process as well as a general vapor deposition process on a front surface and a back surface when forming electrodes in the solar cell.

### Technical Solution

In order to achieve the objective of the present invention, a solar cell having a multiple quantum well structure and a method for fabricating the same forms the quantum well structure by successively performing low-temperature deposition on a thickness of each of a thin-film insulating layer and a thin-film semiconductor layer to 1˜10 nm on a crystalline semiconductor wafer by using an atomic layer deposition (ALD) method, a chemical vapor deposition (CVD) method or a sputtering method, and, then, forms an amorphous or a polycrystalline silicon emitters having an adequate thickness and forms a metallic finger electrode thereon and then forms a SiNx layer as an anti-reflection coating (ARC) layer, and then forms a passivation layer on a bottom surface of the semiconductor wafer, and then forms a metallic electrode on the passivation layer.

At this point, a Back Surface Field (BSF) layer is selectively formed on a bottom surface of the semiconductor wafer in order to reduce a recombination rate at the back surface, and to enhance efficiency of the solar cell resulting from a decrease in series resistance and an increase in an open-circuit voltage.

In addition, the solar cell having a multiple quantum well structure and the method for manufacturing the same according to the present invention performs texturing on the substrate semiconductor wafer before forming the quantum well structure.

Moreover, in the solar cell having a multiple quantum well structure and a method for manufacturing the same according to the present invention, the passivation layer may correspond to any one of an Al2O3 layer, a Si3N4 layer, and a SiO2 layer.

Further, when a p-type silicon or an n-type silicon are used as a starting silicon substrate, although the structure of the quantum well structure is identical, an n-type semiconductor or a p-type semiconductor are respectively used by changing as the semiconductor of the amorphous or polycrystalline emitters.

In order to achieve the objective of the present invention, a solar cell having a quantum well structure and a method for fabricating the same forms a quantum well structure on a semiconductor wafer by successively performing low-temperature deposition on a thickness of each of a thin-film insulating layer and a thin-film semiconductor layer to 1˜10 nm on a crystalline semiconductor wafer by using an atomic layer deposition (ALD) method, a chemical vapor deposition (CVD) method, or a sputtering method, and then forms an amorphous or polycrystalline silicon emitter layer having an adequate thickness, and then forms a SiNx layer as an anti reflection layer, and forms a metallic finger electrode on the anti reflection layer and then forms a passivation layer on a bottom surface of the semiconductor wafer, and then forms a metallic electrode on a bottom surface of the passivation layer.

At this point, a Back Surface Field layer is selectively formed on a bottom surface of the semiconductor wafer in order to reduce a recombination rate at the back surface, and to enhance efficiency of the solar cell resulting from a decrease in serial resistance and an increase in open-circuit voltage.

Additionally, the solar cell having quantum well structure and a method for manufacturing the same according to the present invention performs texturing on the substrate semiconductor wafer before forming the quantum well structure.

Moreover, in the solar cell having a quantum well structure and a method for manufacturing the same according to the present invention, the passivation layer may corresponds to any one of an Al2O3 layer, a Si3N4 layer, and a SiO2 layer.

Further, when p-type silicon and n-type silicon are used as a starting silicon substrate, although the structure of the quantum well is identical, an n-type semiconductor and a p-type semiconductor are respectively used as the semiconductor of the amorphous or polycrystalline emitter.

Furthermore, it is possible to manufacture a broadband (1.2˜1.9 eV) band gap solar cell, wherein the effective band gap is controlled by varying the thickness of a thin-film semiconductor layer, which is sandwiched between thin-film insulating layers, from approximately 1 nm to approximately 10 nm in a multiple quantum well structure.

### Advantageous Effects

As described above, according to the present invention, it is possible to fabricate a broadband (1.2˜1.9 eV) band gap solar cell, wherein the effective band gap is controlled by varying the thickness of a thin-film semiconductor layer, which is sandwiched between thin-film insulating layers from approximately 1 nm to approximately 10 nm in a pn-heterojunction solar cell having a multiple quantum well structure, and, accordingly, a high-efficiency solar cell can be realized due to a decrease in transmission loss of the solar light and a decrease in short wavelength loss in the solar cell.

In addition, according to the present invention, in applying the pn-heterojunction solar cell having a quantum well structure, by using n-type silicon, which has high carrier mobility, as well as p-type silicon as the substrate, a more highly efficient solar cell can be realized.

Furthermore, in order to enhance compatibility in the screen printing method, which is used in the typical manufacturing line of the solar cell, by forming both front surface electrode and back surface electrode by using a screen printing method, the manufacturing cost of the solar cell can be reduced in the present invention as a result of performing minimum change in the existing production line

### BRIEF DESCRIPTION OF THE DRAWINGS

FIG. 1 illustrates a schematic diagram showing band gap energy control of a quantum well structure, which is applied to a solar cell, according to the present invention.

FIG. 2 illustrates an energy band diagram of a solar cell having a multiple quantum well structure according to the present invention.

FIG. 3 illustrates a cross-sectional view of a pn-heterojunction solar cell having a quantum well structure according to a first embodiment of the present invention.

FIG. 4 illustrates a cross-sectional view of a pn-heterojunction solar cell having a quantum well structure according to a second embodiment of the present invention.

FIG. 5 illustrates a cross-sectional view of a pn-heterojunction solar cell having a quantum well structure according to a third embodiment of the present invention.

FIG. 6 illustrates a cross-sectional view of a pn-heterojunction solar cell having a quantum well structure according to a fourth embodiment of the present invention.

### BEST MODE FOR CARRYING OUT THE INVENTION

Various embodiments of the present invention will now be described in more detail with reference to the accompanying drawings. In the drawings, it should be noted that, wherever possible, identical reference numerals will indicate the same components. In the following description, specific features are presented in detail, and such features are provided in order to facilitate the overall understanding of the present invention. Furthermore, in describing the present invention, when the detailed description of related noticed functions or configurations disclosed herein is considered to cause unnecessary ambiguity in the principles of the present invention, the detailed description of the same will be omitted.

In order to realize a high-efficiency silicon-based solar cell, a solar cell having a multiple quantum well structure and a method for manufacturing the same according to the present invention may be related to enhancing conversion efficiency in the solar cell by investigating from which specific part of the solar cell various losses, such as transmission loss, quantum loss, electron-hole recombination loss, surface reflection loss of the solar cell, loss caused by current-voltage characteristics, and so on, occur during the manufacturing process, and by minimizing the various losses by improving the structural design and manufacturing process of the solar cell. Thus, a solar cell having a quantum well structure and a method for manufacturing the same according to the present invention may realize a structure having a multi-layer quantum well structure inserted between p-type and n-type semiconductors of a pn-heterojunction solar cell through an increase in energy gap and a passivation effect.

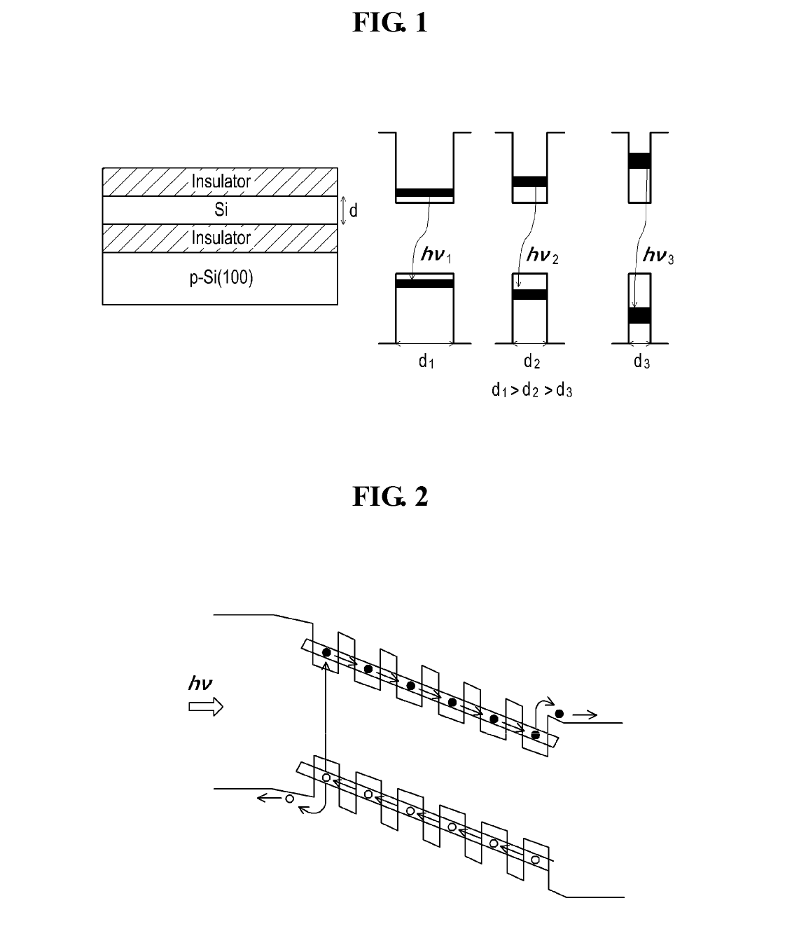

Essentially, at this point, a silicon quantum well, which is sandwiched between insulators, is optimized by adopting silicon. Generally, by reducing a size of single-crystalline silicon to a size that is smaller than the Bohr radius (˜5 nm), quantum confinement occurs, and, due to such quantum confinement, a respective effective band gap may increase, and, when a thickness d of a silicon thin-film is reduced by applying such silicon materials to a multiple quantum well structure, as shown in FIG. 1 and FIG. 2, the band gap (E_{g}) may increase as shown in Formula 1 below.

FIG. 1 illustrates a schematic diagram showing band gap energy control of a quantum well structure, which is applied to a solar cell, according to the present invention, and FIG. 2 illustrates an energy band diagram of a solar cell having a multiple quantum well structure according to the present invention.

$${E}_{g} ∝ \frac{1}{2 {d}^{2}} \qquad [ Formula 1 ]$$

In addition, a passivation effect may occur at an interface of the above-described structure, and, accordingly, a silicon quantum well corresponds to a structure that is advantageous for realizing a silicon integrated tandem solar cell. According to the present invention, a multi-layer quantum well structure is formed by using a quantum confinement effect occurring in a silicon quantum well in order to apply such effect in a high-efficiency solar cell. The solar cell, which uses a structure having the quantum well structure inserted between a p-layer and a n-layer, is expected to achieve high efficiency that can overcome the limitations of the theoretical solar cell conversion efficiency.

The solar cell, which is proposed in the solar cell having a multiple quantum well structure and the method for manufacturing the same according to the present invention, is based upon a device having high efficiency that can overcome the limitations of the theoretical solar cell conversion efficiency (26˜28%) in a material having a single energy threshold.

The solar cell of the present invention has a more enhanced efficiency as compared to a single junction solar cell for the following reasons. Firstly, transmission loss that may occur due to an increase in an absorbable solar spectrum bandwidth respective to a quantum size effect and a multiple band configuration. And, secondly, since a carrier may be moved at a fast rate due to a tunnel effect caused by an electronic bonding between quantum wells, thermal energy loss may be controlled, thereby reducing single wavelength loss.

The solar cell having a multiple quantum well structure and the method for manufacturing the same according to the present invention correspond to a solar cell having a multiple quantum well structure and a method for manufacturing the same that is available for practical usage, wherein a high-efficiency solar cell, which can overcome limitations of the theoretical conversion efficiency can be gained by reducing transmission loss of solar light, which results from an interfacial passivation effect and an increase in the band gap due to quantum confinement, and by reducing short wavelength loss of solar light that is reduced due to high-speed carrier movement resulting from a tunnel effect caused by electronic bonding between quantum wells, may be obtained by inserting a multi-layer quantum well structure between p-type and n-type semiconductors, most particularly, in a pn-heterojunction solar cell, i.e., a solar cell having a heterostructure consisting of a substrate using single-crystalline silicon and an emitter using amorphous or polycrystalline silicon, and when fabricating the solar cell, and wherein the manufacturing cost may be reduced by forming metallic electrodes that are available for a screen printing process on a front surface and a back surface of the solar cell.

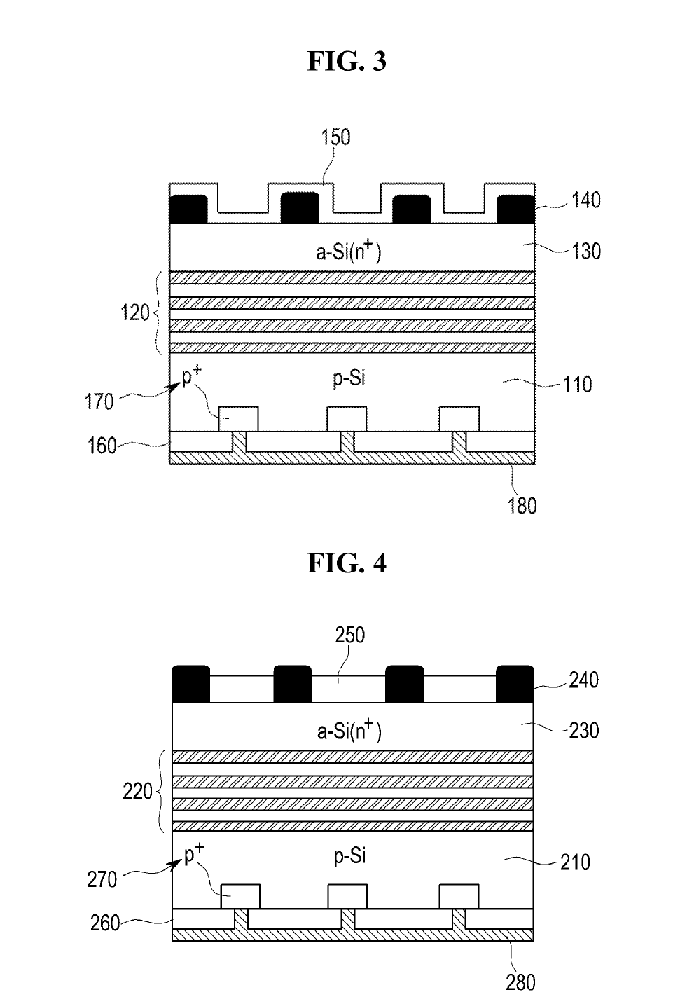

Hereinafter, a method for manufacturing a solar cell having a quantum well structure according to the present invention will be described with reference to FIG. 3 to FIG. 6.

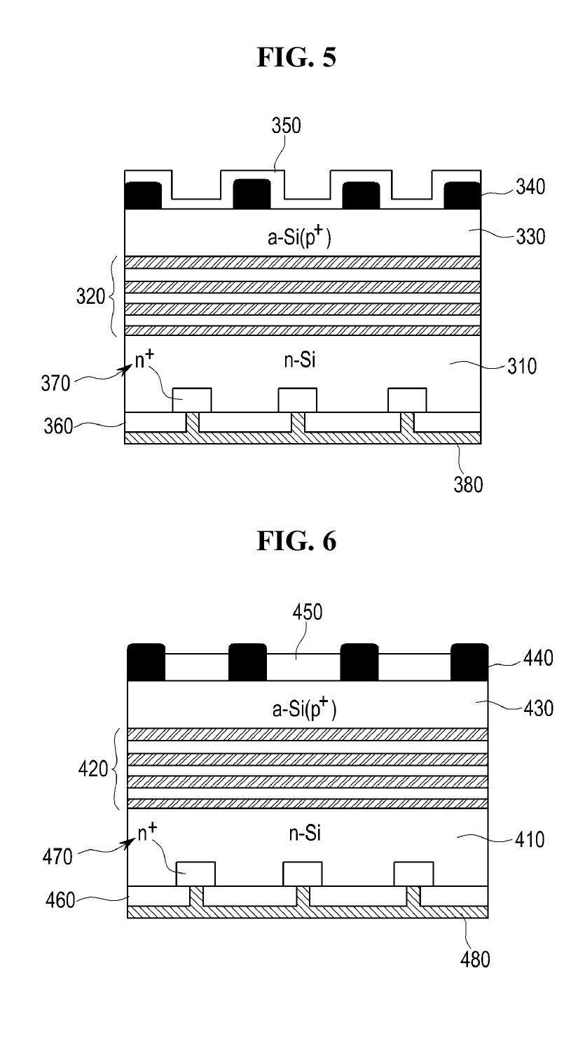

FIG. 3 illustrates a cross-sectional view of a pn-heterojunction solar cell having a quantum well structure according to a first embodiment of the present invention, FIG. 4 illustrates a cross-sectional view of a pn-heterojunction solar cell having a quantum well structure according to a second embodiment of the present invention, FIG. 5 illustrates a cross-sectional view of a pn-heterojunction solar cell having a quantum well structure according to a third embodiment of the present invention, and FIG. 6 illustrates a cross-sectional view of a pn-heterojunction solar cell having a quantum well structure according to a fourth embodiment of the present invention.

First of all, referring to FIG. 3, a pn-heterojunction solar cell having a quantum well structure according to the first embodiment of the present invention is configured of a quantum well structure (120) by successively depositing 1 cycle of a quantum well structure for a required number of cycles (several˜several tens of cycles), wherein each cycle consists of forming a thin-film insulating layer having a thickness of 1˜10 nm on an upper surface of a p-type Si semiconductor wafer (110) by using any one of an atomic layer deposition (ALD) method, a chemical vapor deposition (CVD) method, and a sputtering method, and then form a thin-film semiconductor layer having a thickness of 1˜10 nm on the thin-film insulating layer, and again a thin-film insulating layer upon the thin-film semiconductor layer.

After forming the quantum well structure (120) for the required number of cycles, an emitter layer (130) is formed by forming an n-type silicon, which corresponds to a semiconductor type that is different from the substrate on the quantum well structure (120) in an amorphous or polycrystalline form having an adequate thickness (0.1˜1 μm). Thereafter, a front surface metallic finger electrode (140) is formed on the emitter layer (130) by using a screen printing method or a vapor deposition method. The finger electrode (140) is preferably formed by using silicide in case of using the vapor deposition method, and preferably formed by using an Ag paste in case of using the screen printing method. It is preferable to perform texturing on the semiconductor wafer before forming the quantum well structure (120), and, after forming the finger electrode (140), the semiconductor wafer is dried for a predetermined period of time before forming an anti-reflection layer (150).

Subsequently, a SiNx layer (150) is formed as the Anti-Reflection Coating (ARC) layer on an entire surface in which the metallic finger electrode (140) is formed.

Meanwhile, a Al₂O₃, Si₃N₄, and SiO₂ layer (160), and so on, which configures a protection layer, is formed on a back surface of the semiconductor wafer (110) by using any one of an ALD method, a CVD method, a sputtering method, and a vacuum vapor deposition method. Subsequently, after performing a patterning process for locally generating a back surface field, a p+ layer (170) is formed on a patterned area. Thereafter, a back surface aluminum electrode (180) is formed on the patterned area by using a vacuum vapor deposition method or a screen printing method, just as in the front surface. At this point, when the aluminum electrode (180) is formed by using the screen printing method, it is preferable that the front surface metallic finger electrode (140) and the back surface aluminum electrode (180) are co-fired at the same time.

According to the above-described manufacturing process, the fabrication of a solar cell having a multiple quantum well structure according to the present invention is completed. At this point, after completing the solar cell structure, it is preferable to perform a PMA (post-metallization annealing) process, wherein the completed solar cell structure is processed with a thermal treatment in a nitrogen atmosphere for 30 minutes.

Subsequently, referring to FIG. 4, a pn-heterojunction solar cell having a quantum well structure according to the second embodiment of the present invention is configured of a quantum well structure (220) by successively depositing 1 cycle of a quantum well structure for a required number of cycles (several˜several tens of cycles), wherein each cycle consists of forming a thin-film insulating layer having a thickness of 1˜10 nm on an upper surface of a p-type Si semiconductor wafer (210) by using an ALD method, a CVD method, or a sputtering method, and then form a thin-film semiconductor layer having a thickness of 1˜10 nm on the thin-film insulating layer, and again a thin-film insulating layer upon the thin-film semiconductor layer. After forming the quantum well structure (220) for the required number of cycles, an emitter layer (230) is formed by forming an n-type silicon, which corresponds to a semiconductor type that is different from the substrate on the quantum well structure (220) in an amorphous or polycrystalline form having an adequate thickness (0.1˜1 μm). Thereafter, a SiNx layer (250) is formed as an anti-reflection coating layer, which is formed on a surface of the emitter layer (230). Subsequently, a front surface metallic finger electrode (240) is formed on the anti-reflection layer (250) by using a screen printing method. At this point, it is preferable to perform texturing on the semiconductor wafer before forming the quantum well structure (220), and, after forming the finger electrode (240), the semiconductor wafer is dried for a predetermined period of time before forming the anti-reflection coating layer (250).

Meanwhile, a Al₂O₃, Si₃N₄, and SiO₂ layer (260), and so on, is formed on a back surface of the semiconductor wafer (210) by using an ALD, CVD, sputtering, or vacuum vapor deposition method. Subsequently, after performing a patterning process for locally generating a back surface field, a p+ layer (270) is formed on a patterned area. Thereafter, a back surface aluminum electrode (280) is formed on the patterned area by using a vacuum vapor deposition method or a screen printing method, just as in the front surface.

At this point, when the electrode (280) is formed by using the screen printing method, it is preferable that the front surface metallic finger electrode (240) and the back surface aluminum electrode (280) are co-fired at the same time. Accordingly, a solar cell having a multiple quantum well structure according to the present invention is completed. At this point, after completing the solar cell structure, it is preferable to perform a post-metallization annealing process, wherein the completed solar cell structure is processed with a thermal treatment.

Subsequently, a method for manufacturing a pn-heterojunction solar cell having a multiple quantum well structure according to the third embodiment of the present invention will be described with reference to FIG. 5. As shown in FIG. 5, the third embodiment of the present invention is similar to the manufacturing method and order of the process steps of the first embodiment, which is described above, with the exception of a few steps as described below. More specifically, a starting substrate corresponds to a n-type silicon substrate (310), an emitter electrode corresponds to a p-type electrode (330), and a n+ layer (370) is doped in a patterned area, which is configured for locally generating a back surface field. Most particularly, according to the third embodiment, when electrodes are formed by using a screen printing method, it is preferable that the front surface electrode and the back surface electrode, which are used in the first embodiment, are respectively changed to a back surface electrode and a front surface electrode of the third embodiment, or replaced by adequate metallic electrodes, in order to reduce contact resistance.

Subsequently, referring to FIG. 6, a pn-heterojunction solar cell having a quantum well structure according to the fourth embodiment of the present invention may have a similar manufacturing method and order of the process steps, which are described above with reference to the second embodiment with the exception of a few process steps described below.

More specifically, a starting substrate corresponds to n-type silicon substrate (410), an emitter electrode corresponds to a p-type electrode (430), and a n+ layer (470) is doped in a patterned area for locally generating a back surface field. Most particularly, when electrodes are formed by using a screen printing method in the fourth embodiment, it is preferable that the front surface electrode and the back surface electrode, which are used in the second embodiment, are respectively changed into a back surface electrode and a front surface electrode of the fourth embodiment, or replaced by adequate metallic electrodes, in order to reduce contact resistance.

Although the exemplary embodiment has been described in the detailed description of the present invention, it will be apparent that various modifications and variations can be performed without deviating from the scope and spirit of the present invention. Accordingly, the scope of this present invention should not be limited only to the exemplary embodiment described herein and should be defined by the scope of the appended claims and its equivalents as presented in the description of the present invention.

1. A method for manufacturing a solar cell having a multiple quantum well structure, comprising:
forming a quantum well layer by successively and alternately forming a thin-film insulating layer having a thickness of 1˜10 nm and a thin-film semiconductor layer having a thickness of 1˜10 nm on a p-type or n-type silicon substrate for as many as several˜several tens of cycles;
forming an emitter layer on the quantum well layer by using silicon having a silicon type different from that of the substrate;
forming a metallic finger electrode on the emitter layer;
forming a SiNx layer as an anti-reflection layer on an entire surface of the metallic finger electrode; and
forming a passivation layer on a bottom surface of the substrate.

2. The method of claim 1, comprising:
performing texturing on the silicon substrate before forming the quantum well layer.

3. A method for manufacturing a solar cell having a multiple quantum well structure, comprising:
forming a quantum well layer by successively and alternately forming a thin-film insulating layer having a thickness of 1˜10 nm and a thin-film semiconductor layer having a thickness of 1˜10 nm on a p-type or n-type silicon substrate for as many as several˜several tens of cycles;
forming an emitter layer on the quantum well layer by using silicon having a silicon type different from that of the substrate;
forming a SiNx layer as an anti-reflection layer on an entire surface; and
forming a metallic finger electrode on the anti-reflection layer, and performing heat treatment, so as to allow the metallic finger electrode to contact the emitter layer.

4. The method of claim 3, comprising:
performing texturing the silicon substrate before forming the quantum well layer.

5. A solar cell having a multiple quantum well structure, comprising:
a quantum well layer formed by successively and alternately forming a thin-film insulating layer having a thickness of 1˜10 nm and a thin-film semiconductor layer having a thickness of 1˜10 nm on a p-type or n-type silicon substrate for as many as several˜several tens of cycles;
an emitter layer formed of silicon having a silicon type different from that of the substrate on the quantum well layer;
a metallic finger electrode formed on the emitter layer;
an anti-reflection layer formed of a SiNx layer on an entire surface of the metallic finger electrode; and
a passivation layer formed on a bottom surface of the substrate.

6. The solar cell of claim 5, wherein the emitter layer is configured to have one of an amorphous structure and a polycrystalline structure having a thickness of 0.1˜1 μm.

7. The solar cell of claim 5, wherein the passivation layer corresponds to any one of an Al₂O₃ layer, a Si₃N₄ layer, and a SiO₂ layer.

8. The solar cell of claim 5, wherein a back surface field is further generated by locally doping a high doping layer corresponding to a same type as the substrate on a back surface of the substrate.

9. A solar cell having a multiple quantum well structure, comprising:
a quantum well layer formed by successively and alternately forming a thin-film insulating layer having a thickness of 1˜10 nm and a thin-film semiconductor layer having a thickness of 1˜10 nm on a p-type or n-type silicon substrate for as many as several˜several tens of cycles;
an emitter layer formed of silicon having a silicon type different from that of the substrate on the quantum well layer;
an anti-reflection layer formed of SiNx on an entire surface of the emitter layer; and
a metallic finger electrode formed on the anti-reflection layer and contacting the emitter layer by being processed with a heat treatment.

10. The solar cell of claim 9, wherein the emitter layer is configured to have one of an amorphous structure and a polycrystalline structure having a thickness of 0.1˜1 μm.

11. The solar cell of claim 9, wherein the passivation layer corresponds to any one of an Al2O3 layer, a Si₃N₄ layer, and a SiO₂ layer.

12. The solar cell of claim 9, wherein a back surface field is further generated by locally doping a high doping layer corresponding to a same type as the substrate on a back surface of the substrate.
